(19) United States
(12) Patent Application Publication
(10) Pub. No.: US 2024/0397801 A1
(43) Pub. Date: Nov. 28, 2024

(54) DISPLAY PANEL AND DISPLAY DEVICE

(71) Applicants: Chengdu BOE Optoelectronics Technology Co., Ltd., Chengdu, Sichuan (CN); BOE Technology Group Co., Ltd., Beijing (CN)

(72) Inventors: Bo SHI, Beijing (CN); Ming HU, Beijing (CN); Taofeng XIE, Beijing (CN); Jianji FU, Beijing (CN)

(21) Appl. No.: 18/695,850

(22) PCT Filed: Jul. 28, 2023
(86) PCT No.: PCT/CN2023/110017

§ 371 Date: Mar. 27, 2024

(30) Foreign Application Priority Data
Aug. 19, 2022 (CN) 202210997671.4

(51) Int. Cl. H10K 59/80; H10K 59/35; H10K 59/38

(52) U.S. Cl. CPC H10K 59/879; H10K 59/38; H10K 59/878; H10K 59/8792; H10K 59/35

(57) ABSTRACT

A display panel is provided. The display panel includes: a base substrate; a plurality of light-emitting units disposed on the base substrate; a plurality of protruding structures disposed on the base substrate, wherein the protruding structures correspond to the light-emitting units, and an orthographic projection of the protruding structure on the base substrate surrounds an orthographic projection of a corresponding light-emitting unit on the base substrate; and a first light-transmitting structure disposed on the base substrate provided with the protruding structures, wherein the first light-transmitting structure is disposed between two protruding structures corresponding to two adjacent light-emitting units; the first light-transmitting structure covers at least a portion of a sidewall of the protruding structure; and refractive index of a material of the first light-transmitting structure is greater than refractive index of a material of the protruding structure.

### CROSS-REFERENCE TO RELATED APPLICATIONS

The present disclosure is a U.S. national phase application based on PCT/CN2023/110017, filed on Jul. 28, 2023, which claims priority to Chinese Patent Application No. 202210997671.4, filed on Aug. 19, 2022, and entitled “DISPLAY PANEL AND DISPLAY DEVICE”, all of which are hereby incorporated by reference in their entireties for all purposes.

### TECHNICAL FIELD

The present disclosure relates to the field of display technologies, and in particular, relates to a display panel and a display device.

### BACKGROUND

The display panel is a component capable of performing image display functions.

A display panel includes a base substrate, a plurality of light-emitting units disposed on the base substrate, and an encapsulation film layer disposed above the light-emitting units. The light rays emitted by the light-emitting units can pass through the encapsulation film layer above them to exit the display panel, thereby achieving the display function.

### SUMMARY

Embodiments of the present disclosure provide a display panel and a display device. The technical solutions are as follows:

According to one aspect of the present disclosure, a display panel is provided. The display panel includes:
a base substrate;
a plurality of light-emitting units disposed on the base substrate;
a plurality of protruding structures disposed on the base substrate provided with the light-emitting units, wherein the protruding structures correspond to the light-emitting units, and an orthographic projection of the protruding structure on the base substrate surrounds an orthographic projection of a corresponding light-emitting unit on the base substrate; and
a first light-transmitting structure disposed on the base substrate provided with the protruding structures, wherein the first light-transmitting structure is disposed between two protruding structures corresponding to two adjacent light-emitting units; the first light-transmitting structure covers at least a portion of a sidewall of the protruding structure; and refractive index of a material of the first light-transmitting structure is greater than refractive index of a material of the protruding structure.

In some embodiments, the protruding structure is in a prismoid shape, with dimensions of the protruding structure on one side proximal to the base substrate larger than dimensions of the protruding structure on one side distal to the base substrate.

In some embodiments, the display panel further includes a second light-transmitting structure, wherein the second light-transmitting structure is disposed within a region surrounded by the protruding structure; the second light-transmitting structure covers at least a portion of a sidewall of the protruding structure; and refractive index of a material of the second light-transmitting structure is greater than the refractive index of the material of the protruding structure.

In some embodiments, the display panel further includes a protection layer, wherein the protection layer is disposed on one side of the first light-transmitting structure and the second light-transmitting structure distal to the base substrate, and the protection layer covers the first light-transmitting structure and the second light-transmitting structure.

In some embodiments, refractive index of a material of the protection layer is greater than the refractive index of the material of the first light-transmitting structure, and the refractive index of the material of the protection layer is greater than the refractive index of the material of the second light-transmitting structure.

In some embodiments, the first light-transmitting structure and the protection layer are of an integrated structure.

In some embodiments, the refractive index of the material of the first light-transmitting structure is greater than the refractive index of the material of the second light-transmitting structure.

In some embodiments, the plurality of light-emitting units include two adjacent target light-emitting units, and the first light-transmitting structure includes a first color resistance block and a second color resistance block, wherein the first color resistance block and the second color resistance block are disposed between two protruding structures corresponding to the two adjacent target light-emitting units; and

the second light-transmitting structure includes a third color resistance block and a fourth color resistance block, wherein the third color resistance block and the fourth color resistance block are respectively disposed within regions surrounded by the two protruding structures corresponding to the two adjacent target light-emitting units;

wherein the second color resistance block is disposed on one side of the first color resistance block distal to the third color filter block, the first color resistance block and the fourth color resistance block have a same color, and the second color resistance block and the third color resistance block have a same color.

In some embodiments, a ratio of area A of an orthographic projection of the first color resistance block on the base substrate to area B of an orthographic projection of the second color resistance block on the base substrate, as well as a ratio of area D of an orthographic projection of the fourth color resistance block on the base substrate to area C of an orthographic projection of the third color resistance block on the base substrate satisfy a formula:

$$A / B = x ( D / C ) ;$$

where x is a predetermined coefficient greater than 0.

In some embodiments, the display panel further includes a black matrix pattern and a light-transmitting layer, wherein
the light-emitting units, the black matrix pattern, the light-transmitting layer, and the first light-transmitting structure are arranged sequentially along a direction distal to the base substrate; and
the black matrix pattern is provided with a first opening; a projection of the first light-transmitting structure on the base substrate is located within a projection of the black matrix pattern on the base substrate, and an orthographic projection of the second light-transmitting structure on the base substrate is located within an orthographic projection of the first opening on the base substrate.

In some embodiments, the display panel further includes a first inorganic encapsulation layer, wherein the first inorganic encapsulation layer is disposed between the black matrix pattern and the light-emitting units;
the light-transmitting layer includes an organic encapsulation layer and a second inorganic encapsulation layer, with the second inorganic encapsulation layer disposed on one side of the organic encapsulation layer distal to the black matrix.

In some embodiments, the black matrix pattern and the first light-transmitting structure are separated by a first distance in a direction perpendicular to the base substrate, and the black matrix pattern and the light-emitting unit are separated by a second distance in the direction perpendicular to the base substrate, with a ratio of the first distance to the second distance greater than or equal to 2.

In some embodiments, the display panel further includes a pixel definition layer, wherein the pixel definition layer is provided with pixel openings, and the light-emitting units are disposed within the pixel openings;
an edge of the orthographic projection of the protruding structure on the base substrate and an edge of an orthographic projection of the pixel opening on the base substrate are separated by a specified distance, the specified distance being greater than or equal to 0 micron and less than or equal to 5 microns.

In some embodiments, the protruding structure includes a top surface, a bottom surface, and a sidewall connecting the bottom surface and the top surface, an included angle between the sidewall and the bottom surface is in a range of 20° to 90°.

According to another aspect of the present disclosure, a display device is provided. The display device includes the display panel described above.

### BRIEF DESCRIPTION OF THE DRAWINGS

To describe the technical solutions in the embodiments of the present disclosure more clearly, the following briefly describes the accompanying drawings required for describing the embodiments. Apparently, the accompanying drawings in the following description show merely some embodiments of the present disclosure, and a person of ordinary skill in the art may still derive other drawings from these accompanying drawings without creative efforts.

FIG. 1 is a schematic structural diagram of a display panel;

FIG. 2 is a schematic structural diagram of a display panel according to some embodiments of the present disclosure;

FIG. 3 is a schematic diagram of the cross-sectional structure at the A1-A2 position of the display panel shown in FIG. 2;

FIG. 4 is a schematic structural diagram of another display panel according to some embodiments of the present disclosure;

FIG. 5 is a schematic structural diagram of a protruding structure according to some embodiments of the present disclosure;

FIG. 6 is a schematic structural diagram of another display panel according to some embodiments of the present disclosure;

FIG. 7 is a schematic diagram of the cross-sectional structure at the B1-B2 position of the display panel shown in FIG. 6;

FIG. 8 is a schematic structural diagram of another display panel according to some embodiments of the present disclosure;

FIG. 9 is a schematic structural diagram of another display panel according to some embodiments of the present disclosure;

FIG. 10 is a schematic structural diagram of another display panel according to some embodiments of the present disclosure;

FIG. 11 is a schematic structural diagram of another display panel according to some embodiments of the present disclosure;

FIG. 12 is a schematic diagram of the cross-sectional structure at the C1-C2 position of the display panel shown in FIG. 11;

FIG. 13 is a schematic structural diagram of another display panel according to some embodiments of the present disclosure;

FIG. 14 is a schematic structural diagram of another display panel illustrated according to some embodiments of the present disclosure;

FIG. 15 is a flowchart illustrating a method for manufacturing a display panel according to some embodiments of the present disclosure; and

FIG. 16 is a schematic structural diagram of the process for manufacturing the display panel corresponding to FIG. 15.

The above accompanying drawings have illustrated the explicit embodiments of the present disclosure, which will be described below in detail. These accompanying drawings and textual descriptions are not intended to limit the scope of the conception of the present disclosure in any way, but rather to assist those skilled in the art in understanding the concepts of the present disclosure by referring to specific embodiments.

### DETAILED DESCRIPTION

For clearer descriptions of the objectives, technical solutions, and advantages of the present disclosure, embodiments of the present disclosure are further described in detail below with reference to the accompanying drawings.

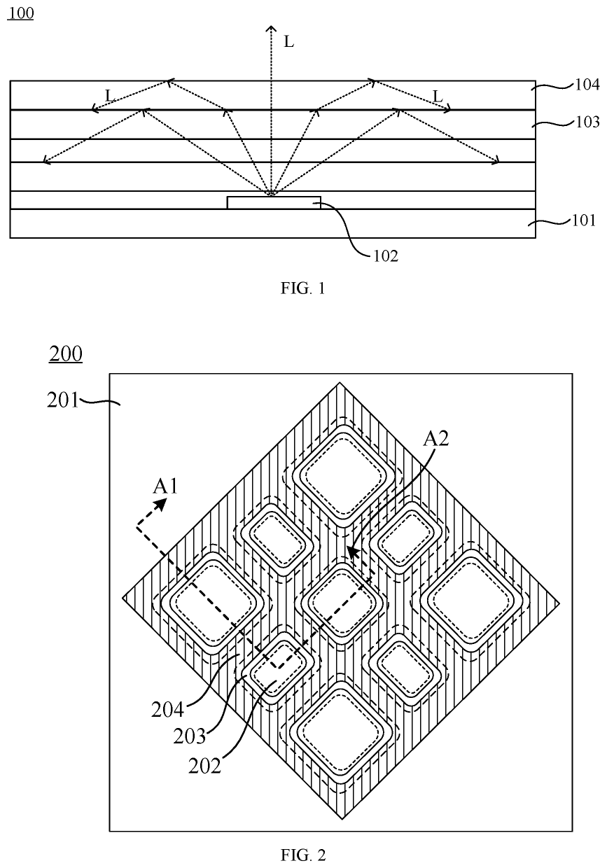

FIG. 1 is a schematic structural diagram of a display panel. The display panel 100 includes a base substrate 101, a plurality of light-emitting units (only one light-emitting unit is shown in FIG. 1 for illustration purposes) 102 disposed on the base substrate 101, a first light-transmitting layer 103 and a second light-transmitting layer 104 disposed on the base substrate provided with the plurality of light-emitting units 102.

The light-emitting unit 102 includes at least one of organic light-emitting diodes (OLED) and quantum dot light-emitting diodes (QLED). The light-emitting unit 102 includes light-emitting devices for emitting various colored lights, exemplarily including red light-emitting devices for emitting red light, blue light-emitting devices for emitting blue light, and green light-emitting devices for emitting green light. By employing light-emitting devices capable of emitting various colored lights, the display panel can display images. Upon activation of the display panel 100, the light-emitting unit 102 emits light rays L, which can exit the display panel 100 to achieve the function of image display.

In the above-mentioned display panel, the first light-transmitting layer 103 and the second light-transmitting layer 104 on the display panel are made of different materials and have different refractive indices. In the case that the refractive index of the first light-transmitting layer 103 is greater than that of the second light-transmitting layer 104, a part of the light rays emitted by the light-emitting unit 102 can be total reflection display at the interface between the first light-transmitting layer 103 and the second light-transmitting layer 104, resulting in a reduction in the front luminous efficiency of the display substrate. Moreover, the light rays emitted by the light-emitting unit 102 exit into the external environment (e.g., air) from the second light-transmitting layer. The refractive index of the second light-transmitting layer is greater than that of the external environment. In the case that the incident angle of a light ray at the interface between the second light-transmitting layer and the external environment is greater than or equal to the critical angle for total reflection, the light ray is capable of total reflection, further leading to a lower overall luminous efficiency of the display panel.

The embodiments of the present disclosure provide a display panel, a method for manufacturing the display panel, and a display device, which can solve problems in the related art.

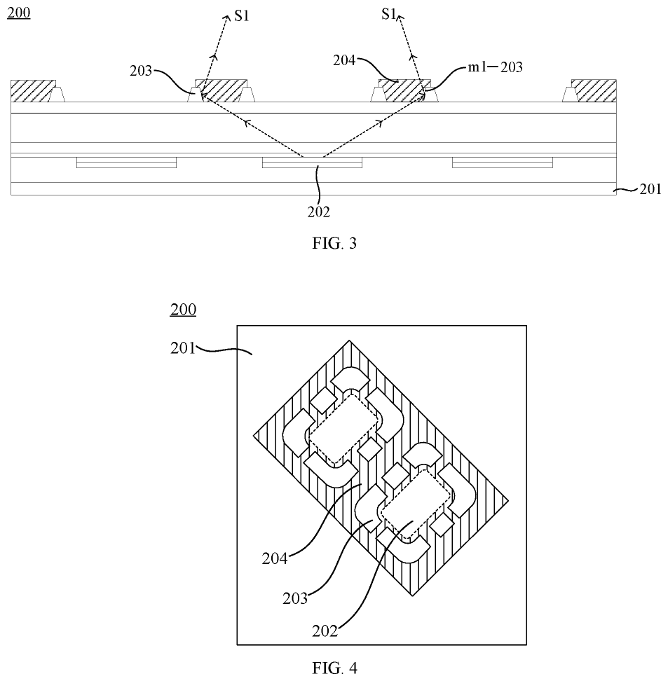

Referring to FIG. 2 and FIG. 3, FIG. 2 is a schematic structural diagram of a display panel 200 according to some embodiments of the present disclosure, and FIG. 3 is a schematic diagram of the cross-sectional structure at the A1-A2 position of the display panel 200 shown in FIG. 2. The display panel 200 includes a base substrate 201, a plurality of light-emitting units 202, a plurality of protruding structures 203, and a first light-transmitting structure 204.

The plurality of light-emitting units 202 are disposed on the base substrate 201, and the plurality of light-emitting units 202 are arranged in an array on the base substrate 201. The light-emitting unit 202 includes at least one light-emitting device.

The plurality of protruding structures 203 are disposed on the base substrate 201 provided with the light-emitting units 202. The protruding structures 203 correspond to the light-emitting units 202, and an orthographic projection of each protruding structure 203 on the base substrate 201 surrounds an orthographic projection of the corresponding light-emitting unit 202 on the base substrate 201. The orthographic projection of the protruding structure 203 on the base substrate 201 does not overlap with the orthographic projection of the light-emitting unit 202 on the base substrate 201. Moreover, the protruding structure 203 is disposed on the side of the light-emitting unit 202 distal to the base substrate 201.

The first light-transmitting structure 204 is disposed on the base substrate 201 provided with the protruding structures 203. The first light-transmitting structure 204 is disposed between two protruding structures 203 corresponding to two adjacent light-emitting units 202. Moreover, the first light-transmitting structure 204 covers at least a portion of the sidewall m1 of the protruding structure 203, and the refractive index of the material of the first light-transmitting structure 204 is greater than the refractive index of the material of the protruding structure 203. The first light-transmitting structure 204 fills the gap between two adjacent protruding structures 203 corresponding to two light-emitting units 202.

As shown in FIG. 3, the light rays emitted by the light-emitting unit 202 include at least the light rays S1. The light ray S1 can be emitted by the light-emitting unit 202, enter the first light-transmitting structure 204 disposed between two protruding structures 203, and then irradiate to the sidewall m1 of the protruding structure 203 through the first light-transmitting structure 204. This sidewall m1 is the interface between the first light-transmitting structure 204 and the protruding structures 203. As the refractive index of the first light-transmitting structure 204 is greater than that of the protruding structure 203, the light ray S1 is in a state of directing from an optically denser medium to an optically thinner medium. Based on the principle of total reflection, a part of the light ray S1 is totally reflected at the sidewall m1 of the protruding structure 203, and directed towards the region directly facing the display panel 200, thereby improving the front luminous efficiency of the display panel 200. That is, the display substrate according to the embodiments of the present disclosure, by providing protruding structures 203, increases the total reflection interface for the light rays emitted by the light-emitting unit 202, thereby improving the luminous efficiency of the display panel 200.

In summary, a display panel is provided according to the embodiments of the present disclosure, which includes a base substrate, a plurality of light-emitting units, a plurality of protruding structures, and a first light-transmitting structure. The first light-transmitting structure is disposed between two protruding structures corresponding to two adjacent light-emitting units, the first light-transmitting structure covers at least a portion of the sidewall of the protruding structure, and the refractive index of the first light-transmitting structure is greater than that of the protruding structure. In this way, the interface between the first light-transmitting structure and the protruding structure can reflect part of the light rays emitted by the light-emitting unit to the region directly facing the display panel, so as to improve the luminous efficiency of the display panel, solve the problem of low luminous efficiency of display panels in related art, and achieve the effect that improves the luminous efficiency of the display panel.

In some embodiments, the base substrate 201 is a glass substrate or a polyimide substrate. The base substrate 201 is further provided with a driver device, which is configured to drive the light-emitting units 202 to emit light. The light-emitting units 202, when emitting light, emit light rays in various directions within a 180-degree range on the side of the base substrate 201 provided with the light-emitting units 202. However, a viewer typically views the display panel 200 from a region directly facing the display panel 200, which results in part of the light rays emitted by the light-emitting units 202 not being directed towards the region where the viewers are located, leading to a waste of light rays. In the display panel 200 in the embodiments of the present disclosure, a part of the light beams irradiated onto the sidewall m1 of the protruding structure 203 is total reflected on the sidewall m1 and emitted to the region directly facing the display panel 200, such that the front luminous efficiency of the display panel 200 can be improved.

FIG. 4 is a schematic structural diagram of another display panel 200 according to some embodiments of the present disclosure, as shown in FIG. 4. In some embodiments, the protruding structure 203 is of a continuous structure or consists of a plurality of discontinuous structures. Specifically, the protruding structure 203 is a continuous annular structure, or the protruding structure 203 includes a plurality of sub-protruding structures 203. The plurality of sub-protruding structures 203 are arranged at intervals along the periphery of the light-emitting unit 202. In this way, a part of the light rays emitted by the light-emitting unit 202 can pass through the gap region between adjacent sub-protruding structures 203 and exit the display panel 200, such that the luminous output of the display panel 200 can be adjusted by adjusting the number of protruding structures 203.

It should be noted that in the display panel 200 in the embodiments of the present disclosure, one or more light-emitting units 202 are not provided with corresponding protruding structures 203 on the side distal to the base substrate 201. Alternatively, each light-emitting unit 202 among a plurality of light-emitting units 202 is provided with a corresponding protruding structure 203 on the side distal to the base substrate 201, which can further improve the overall luminous efficiency of the display panel 200. Exemplarily, the light-emitting units 202 and the protruding structures 203 are in one-to-one correspondence, which is not limited in the embodiments of the present disclosure.

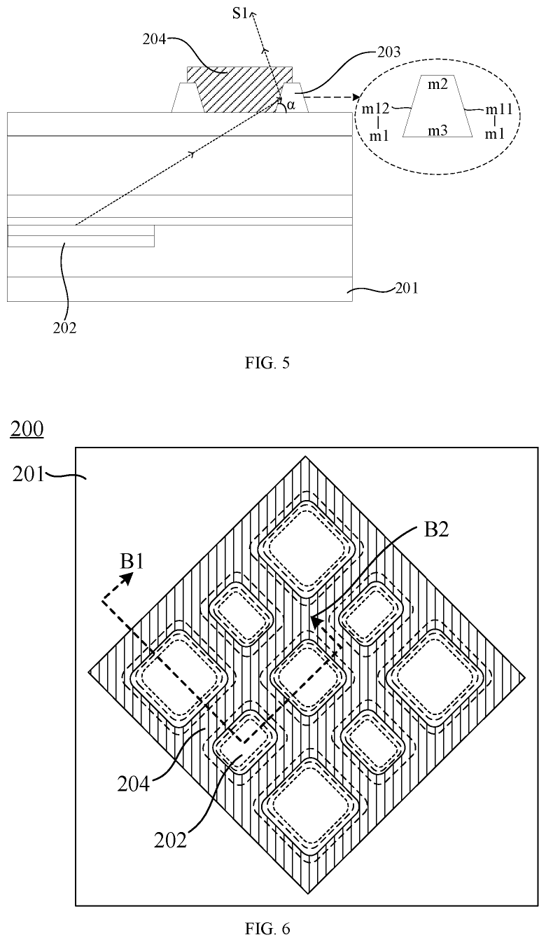

Referring to FIG. 5, FIG. 5 is a schematic structural diagram of a protruding structure 203 according to some embodiments of the present disclosure. In some embodiments, the protruding structure 203 is in a prismoid shape, with the dimensions of the protruding structure 203 on the side proximal to the base substrate 201 larger than the dimensions of the protruding structure 203 on the side distal to the base substrate 201. The protruding structure 203 includes a top surface m2, a bottom surface m3, and a sidewall m1 connecting the bottom surface m3 and the top surface m2. The dimensions of the protruding structure 203 gradually decrease in the direction distal to the base substrate 201. The cross-sectional shape of the protruding structure 203 along the direction perpendicular to the base substrate 201 is trapezoidal. In this way, the sidewall m1 of the protruding structure 203 is advantageous in improving the luminous efficiency of the display panel 200.

In some embodiments, as shown in FIG. 5, the protruding structure 203 includes two sidewalls m1 (a first sidewall m11 and a second sidewall m12). The second sidewall m12 is an inclined surface inclining towards the center of the protruding structure 203. With such an inclined surface structure, the interface between the protruding structure 203 and the first light-transmitting structure 204 is at the second sidewall m12, and the refractive index of the first light-transmitting structure 204 is greater than the refractive index of the protruding structure 203, such that the inclined second sidewall m12 can adjust the direction of the light rays emitted by the light-emitting unit 202, thereby improving the luminous efficiency of the display panel 200. In the embodiments of the present disclosure, the mentioned “a surface inclining towards a direction” can refer to the surface with a first edge and a second edge arranged along that direction, wherein the first edge and the second edge are two opposite edges of the surface, with the first edge disposed on the side of the second edge distal to the base substrate 201.

In some embodiments, the included angle α between the sidewall m1 and the bottom surface m3 is in the range of 20° to 90°. Further, the included angle α between the sidewall m1 and the bottom surface m3 is in the range of 45° to 75°. Within this range, the luminous efficiency of the display panel 200 is further improved. It should be noted that in the embodiments of the present disclosure, the included angles between the two sidewalls m1 (the first sidewall m11 and the second sidewall m12) and the bottom surface m3 of the protruding structure 203 may be the same or may be different, which are not limited in the embodiments of the present disclosure.

In some embodiments, the width of the protruding structure 203 is in the range of 3 microns to 5 microns, wherein the width of the protruding structure 203 refers to the dimension of the protruding structure 203 in the direction perpendicular to the extending direction. The thickness of the protruding structure 203 is in the range of 1 micron to 5 microns, wherein the thickness of the protruding structure 203 refers to the dimension of the protruding structure 203 in the direction perpendicular to the base substrate 201. The material of the protruding structure 203 includes optical clear adhesive (OCA), and the refractive index of the material of the protruding structure 203 is in the range of 1.45 to 1.5. The material of the first light-transmitting structure 204 includes optical clear adhesive, and the refractive index of the material of the first light-transmitting structure 204 is in the range of 1.65 to 1.75.

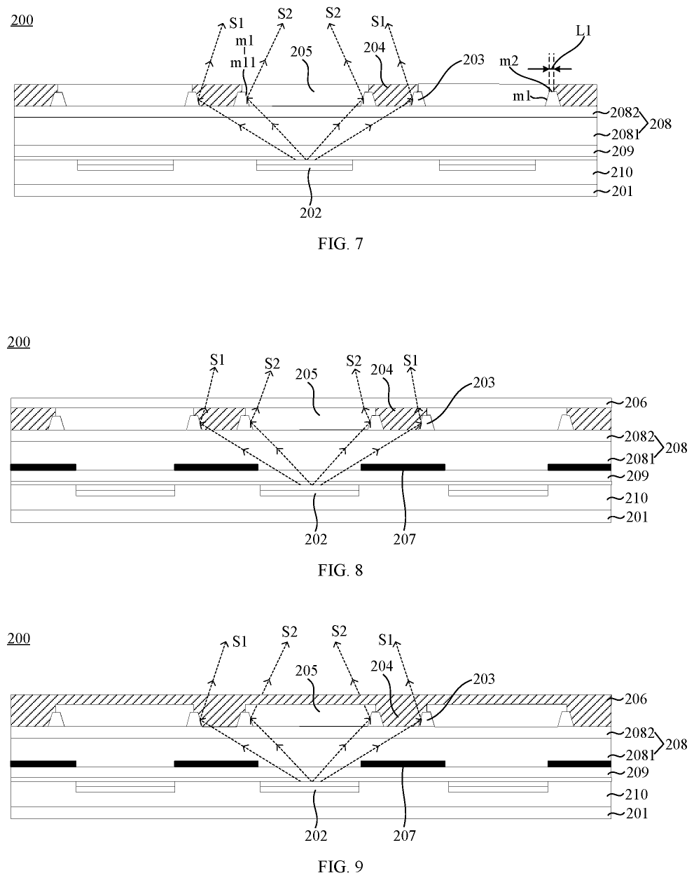

Referring to FIG. 6 and FIG. 7, FIG. 6 is a schematic structural diagram of another display panel 200 according to some embodiments of the present disclosure, and FIG. 7 is a schematic diagram of the cross-sectional structure at the B1-B2 position of the display panel 200 shown in FIG. 6. In some embodiments, the display panel 200 further includes a second light-transmitting structure 205. The second light-transmitting structure 205 is disposed within the region surrounded by the protruding structure 203. The second light-transmitting structure 205 covers at least a portion of the sidewall m1 of the protruding structure 203. The refractive index of the material of the second light-transmitting structure 205 is greater than the refractive index of the material of the protruding structure 203. The second light-transmitting structure 205 is disposed on the base substrate 201 provided with the protruding structure 203. The second light-transmitting structure 205 and the first light-transmitting structure 204 are disposed on either side of the protruding structure 203 in the extending direction of the protruding structure 203. The orthographic projection of the second light-transmitting structure 205 on the base substrate 201 overlaps with the orthographic projection of the light-emitting unit 202 on the base substrate 201.

As shown in FIG. 7, the light rays emitted by the light-emitting unit 202 include at least the light rays S2. The light ray S2 can be emitted by the light-emitting unit 202, enter the second light-transmitting structure 205 disposed within the protruding structure 203, and then irradiate to the sidewall m1 of the protruding structure 203 (where the sidewall m1 is the first sidewall m11 of the protruding structure 203) through the second light-transmitting structure 205 layer. The sidewall m1 is the interface between the second light-transmitting structure 205 and the protruding structure 203. As the refractive index of the second light-transmitting structure 205 is greater than that of the protruding structure 203, the light ray S2 is in a state of directing from an optically denser medium to an optically thinner medium. Based on the principle of total reflection, a part of the light ray S2 is totally reflected at the sidewall m1 of the protruding structure 203, directing towards the region directly facing the display panel 200, thereby improving the front luminous efficiency of the display panel 200. The display substrate according to the embodiments of the present disclosure, by providing the second light-transmitting structure 205 in contact with the protruding structure 203, further increases the total reflection interface for the light rays emitted by the light-emitting unit 202, thereby improving the luminous efficiency of the display panel 200.

The material of the second light-transmitting structure 205 includes optical clear adhesive, and the refractive index of the material of the second light-transmitting structure 205 is in the range of 1.65 to 1.75.

In some embodiments, as shown in FIG. 7, the second light-transmitting structure 205 covers the sidewall m1 and the edge region of the top surface m2 of the protruding structure 203. The edge region is defined as the region that extends a specified distance L1 from the edge where the top surface m2 of the protruding structure 203 is connected with the sidewall m1 of the protruding structure 203 towards the center of the top surface m2 of the protruding structure 203. The center refers to the center of the top surface m2 of the protruding structure 203 in the direction perpendicular to the extending direction of the protruding structure 203. The specified distance L1 is in the range of 0 micron to 2 microns. In this way, a gap between the second light-transmitting structure 205 and the protruding structure 203 can be avoided to ensure that the second light-transmitting structure 205 and the sidewall m1 of the protruding structure 203 fit together. Similarly, the first light-transmitting structure 204 can also cover the sidewall m1 and the edge region of the top surface m2 of the protruding structure 203.

Exemplarily, the luminous output of the display panel provided with the protruding structures, the first light-transmitting structure, and the second light-transmitting structure in the embodiments of the present disclosure, when compared to the luminous output of a display panel without these structures in the related art, has increased by 36.3% based on the luminous output of the display panel in the related art.

Referring to FIG. 8, FIG. 8 is a schematic structural diagram of another display panel 200 according to some embodiments of the present disclosure. In some embodiments, the display panel 200 further includes a protection layer 206. The protection layer 206 is disposed on the side of the first light-transmitting structure 204 and the second light-transmitting structure 205 distal to the base substrate 201, and the protection layer 206 covers the first light-transmitting structure 204 and the second light-transmitting structure 205. The protection layer 206 serves as a planarization layer. The material of the protection layer 206 includes polyethylene glycol terephthalate (PET) or optical clear adhesive.

Exemplarily, the material of the protection layer 206 is polyethylene glycol terephthalate, which can enable the protection layer 206 to have better physical and mechanical properties, such as better fatigue resistance, friction resistance, and dimensional stability. This serves to protect the first light-transmitting structure 204 and the second light-transmitting structure 205 on the side distal to the base substrate 201.

Alternatively, the material of the protection layer 206 is optical clear adhesive, which can enable the protection layer 206 to have better transparency and flatness. This enhances the flatness of one surface of the protection layer 206 distal to the base substrate 201. In this way, the display panel 200 can have a smoother surface on the side displaying images, thereby improving the display effect of the display panel 200.

In some embodiments, the refractive index of the material of the protection layer 206 is greater than the refractive index of the material of the first light-transmitting structure 204, and the refractive index of the material of the protection layer 206 is greater than the refractive index of the material of the second light-transmitting structure 205. As shown in FIG. 8, the light rays emitted by the light-emitting unit 202 include at least the light rays S1 and light rays S2. The light rays S1 and S2 can be totally reflected on the sidewall m1 of the protruding structure 203, then irradiate to the protection layer 206 through the first light-transmitting structure 204 and the second light-transmitting structure 205, respectively. The refractive index of the protection layer 206 is larger than that of both the first light-transmitting structure 204 and the second light-transmitting structure 205, therefore, when the light ray S1 is irradiated onto the interface between the first light-transmitting structure 204 and the protection layer 206, the light ray S1 is refracted towards the direction of the normal near the interface. Similarly, the light ray S2 is also refracted towards the direction of the normal near the interface. This further directs the light ray S1 towards the region directly facing the display panel 200, thereby improving the luminous efficiency of the display panel 200.

Moreover, this results in a smaller included angle between the light ray incident on the protection layer 206 and the normal to the surface of the protection layer 206. The surface is on the side of the protection layer 206 distal to the base substrate 201, and the surface serves as the interface between the protection layer 206 and the external environment. In this way, the incident angle of the light ray on the surface can be avoided to be greater than or equal to the total reflection critical angle, the total internal reflection of the light ray on the surface can be avoided, and the overall luminous efficiency of the display panel 200 can be improved.

In some embodiments, as shown in FIG. 9, which is a schematic structural diagram of another display panel 200 according to some embodiments of the present disclosure, the first light-transmitting structure 204 and the protection layer 206 are of an integrated structure. The first light-transmitting structure 204 and the protection layer 206 are formed in a single process, and the materials of the first light-transmitting structure 204 and the protection layer 206 are the same, so as to simplify the manufacturing process of the display panel 200.

In some embodiments, the refractive index of the first light-transmitting structure 204 is greater than that of the second light-transmitting structure 205. The materials of the first light-transmitting structure 204 and the protection layer 206 are the same, which ensures that the refractive index of the film layer of the second light-transmitting structure 205 on the side distal to the base substrate 201 is greater than the refractive index of the second light-transmitting structure 205, and further allows light rays passing through the second light-transmitting structure 205 to be directed towards the region directly facing the display panel 200, thereby improving the luminous efficiency of the display panel 200.

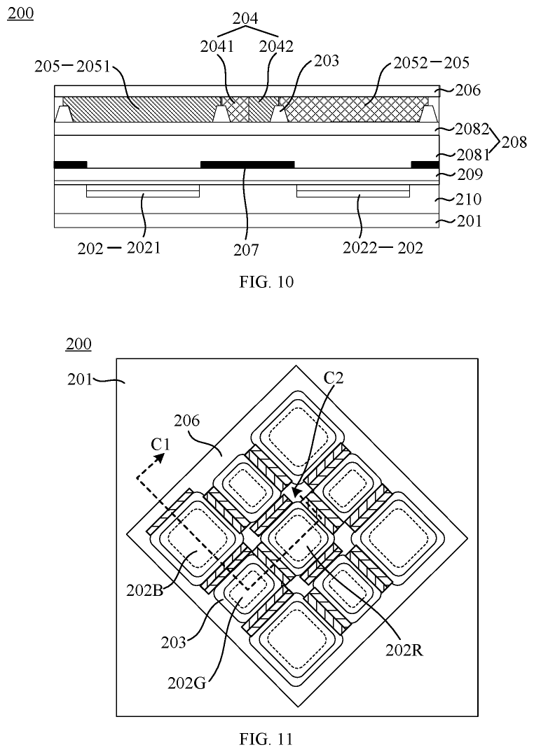

Referring to FIG. 10, FIG. 10 is a schematic structural diagram of another display panel 200 according to some embodiments of the present disclosure. It should be noted that in FIG. 10, the same pattern is filled for color resistance blocks with the same color to clearly illustrate color resistance blocks of the same color. In some embodiments, the plurality of light-emitting units 202 include two adjacent target light-emitting units 202, and the two target light-emitting units 202 are the first light-emitting unit 2021 and the second light-emitting unit 2022. The first light-emitting unit 2021 and the second light-emitting unit 2022 emit light rays of different colors. In the embodiments of the present disclosure, each light-emitting unit 202 includes a light-emitting device, and the light-emitting device may be a blue light-emitting device for emitting blue light rays, a red light-emitting device for emitting red light rays, and a green light-emitting device for emitting green light rays.

The first light-transmitting structure 204 includes a first color resistance block 2041 and a second color resistance block 2042. The first color resistance block 2041 and the second color resistance block 2042 are disposed between two protruding structures 203 corresponding to two adjacent target light-emitting units 202. The second light-transmitting structure 205 includes a third color resistance block 2051 and a fourth color resistance block 2052. The third color resistance block 2051 and the fourth color resistance block 2052 are respectively disposed within the regions surrounded by the two protruding structures 203 corresponding to the two adjacent target light-emitting units 202.

The second color resistance block 2042 is disposed on the side of the first color resistance block 2041 distal to the third color filter block 2051. The first color resistance block 2041 is disposed on the side of the second color resistance block 2042 distal to the fourth color resistance block 2052. The first color resistance block 2041 and the fourth color resistance block 2052 have the same color, and the second color resistance block 2042 and the third color resistance block 2051 have the same color.

Exemplarily, the two protruding structures 203 include the first protruding structure 203 and the second protruding structure 203. The third color resistance block 2051 is disposed on the inner side of the first protruding structure 203, the first color resistance block 2041 is disposed on the outer side of the first protruding structure 203, and the third color resistance block 2051 and the first color resistance block 2041 each cover one of the two sidewalls m1 of the first protruding structure 203. The fourth color resistance block 2052 is disposed on the inner side of the second protruding structure 203, the second color resistance block 2042 is disposed on the outer side of the second protruding structure 203, and the fourth color resistance block 2052 and the second color resistance block 2042 each cover one of the two sidewalls m1 of the second protruding structure 203.

In this way, the first light-transmitting structure 204 and the second light-transmitting structure 205 serve as a color filter film layer. The color filter film layer is the film layer that includes the aforementioned color resistance blocks, and the color resistance blocks are in one-to-one correspondence with the light-emitting units 202. The projection area of the light-emitting unit 202 on the color resistance layer is located within the color filter film layer. The colors of the light emitted by the light-emitting units 202 include red, green, and blue, and the colors of the color resistance blocks correspond to the colors of the respective light-emitting devices.

In some embodiments of the present disclosure, the first color resistance block 2041 and the second color resistance block 2042 are also provided between two protruding structures 203, which not only enhances the front luminous output of the display panel 200, but also prevents color mixing at the first light-transmitting structure 204 between the two protruding structures 203, thereby facilitating the control of the emitted brightness of light rays in various colors on the display panel 200.

It should be noted that in the embodiments of the present disclosure, the light rays emitted by the first light-emitting unit 2021 with smaller emission angles can irradiate to the third color resistance block 2051, and the light rays emitted by the first light-emitting unit 2021 with larger emission angles can irradiate to the interface between the second color resistance block 2042 and the protruding structure 203, at which total reflection occurs, the second color resistance block 2042 and the third color resistance block 2051 can be set to have the same color. The color of the third color resistance block 2051 is the same as the color of the light rays emitted by the first light-emitting unit 2021, and similarly, the first color resistance block 2041 and the fourth color resistance block 2052 can be set to have the same color.

In some embodiments, the ratio of area A of the orthographic projection of the first color resistance block 2041 on the base substrate 201 to area B of the orthographic projection of the second color resistance block 2042 on the base substrate 201, as well as the ratio of area D of the orthographic projection of the fourth color resistance block 2052 on the base substrate 201 to area C of the orthographic projection of the third color resistance block 2051 on the base substrate 201 satisfy the following formula:

$$A / B = x ( D / C ) ;$$

wherein x is a predetermined coefficient greater than 0. The dimensions of the light-emitting units 202 of different colors in the display panel 200 vary, and the dimensions of color resistance blocks also vary. As the colors of the first color resistance block 2041 and the fourth color resistance block 2052 are the same, and the colors of the second color resistance block 2042 and the third color resistance block 2051 are the same, the dimensions of the first color resistance block 2041 and the second color resistance block 2042 are configured based on the dimensions of color resistance blocks with the same color, which avoids deviations between the color ratio of the light rays emitted from the display panel 200 and the predetermined ratio. Exemplarily, the aforementioned x is 1. Alternatively, the aforementioned x is 0.5, 0.8, 1.5, 2, etc.

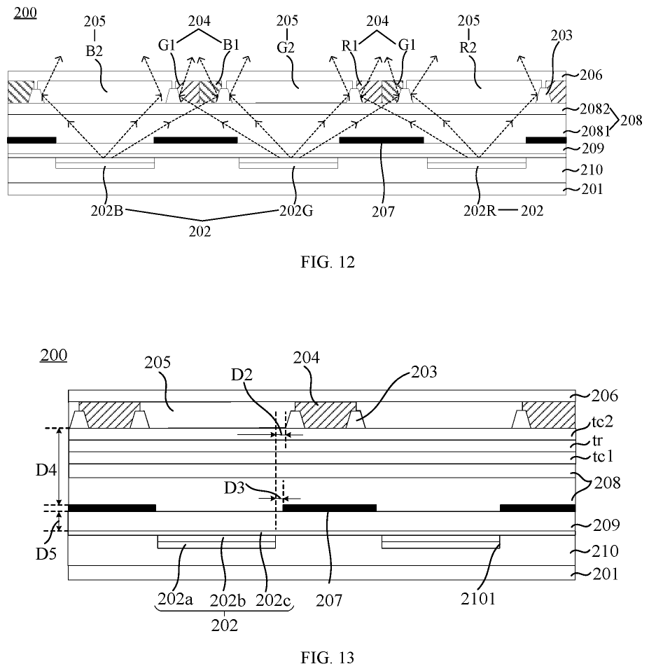

Exemplarily, FIG. 11 is a schematic structural diagram of another display panel 200 according to some embodiments of the present disclosure, and FIG. 12 is a schematic diagram of the cross-sectional structure at the C1-C2 position of the display panel 200 shown in FIG. 11. The plurality of light-emitting units include a blue light-emitting unit 200B, a green light-emitting unit 200G, and a red light-emitting unit 200R. The first light-transmitting structure 204 includes a first red color resistance block R1, a first green color resistance block G1, and a first blue color resistance block B1. The second light-transmitting structure 205 includes a second red color resistance block R2, a second green color resistance block G2, and a second blue color resistance block B2. The first red color resistance block R1 and the second red color resistance block R2 are formed using the same patterning process. The first blue color resistance block B1 and the second blue color resistance block B2 are formed using the same patterning process. The first green color resistance block G1 and the second green color resistance block G2 are formed using the same patterning process. This reduces the manufacturing steps of the display panel.

In some embodiments, as shown in FIG. 12, the display panel 200 further includes a black matrix pattern 207 and a light-transmitting layer 208. The light-emitting units 202, the black matrix pattern 207, the light-transmitting layer 208, and the first light-transmitting structure 204 are arranged sequentially along the direction distal to the base substrate 201.

The black matrix pattern 207 is provided with a first opening. The projection of the first light-transmitting structure 204 on the base substrate 201 is located within the projection of the black matrix pattern 207 on the base substrate 201. The orthographic projection of the second light-transmitting structure 205 on the base substrate 201 is located within the orthographic projection of the first opening on the base substrate 201.

The display panel 200 further includes a first inorganic encapsulation layer 209 (also referred to as a CVD1 layer), and the first inorganic encapsulation layer 209 is disposed between the black matrix pattern 207 and the light-emitting units 202. The light-transmitting layer 208 includes an organic encapsulation layer 2081 (also referred to as an inkjet printing layer IJP) and a second inorganic encapsulation layer 2082 (also referred to as a CVD2 layer). The light-transmitting layer 208 includes the organic encapsulation layer 2081 and the second inorganic encapsulation layer 2082, with the second inorganic encapsulation layer 2082 disposed on the side of the organic encapsulation layer 2081 distal to the black matrix pattern 207. That is, the organic encapsulation layer 2081 and the second inorganic encapsulation layer 2082 are disposed on the side of the black matrix pattern 207 distal to the base substrate 201 and are laminated sequentially along the direction distal to the black matrix pattern 207. The black matrix pattern 207 is disposed on the side of the organic encapsulation layer 2081 close to the base substrate 201, and the protruding structures 203 is disposed on the side of the second inorganic encapsulation layer 2082 distal to the base substrate 201.

In this way, the light-transmitting layer 208 is disposed between the black matrix pattern 207 and the first light-transmitting structure 204, which allows the light beams emitted by the light-emitting unit 202 from irradiating to the first light-transmitting structure 204, and prevents the black matrix pattern 207 from blocking the light beams emitted by the light-emitting unit 202, thereby improving the luminous efficiency of the display panel 200. Additionally, the black matrix pattern 207 is also configured to absorb external light rays, achieving an anti-glare effect.

In some embodiments, as shown in FIG. 13, the black matrix pattern 207 and the first light-transmitting structure 204 are separated by a first distance D4 in the direction perpendicular to the base substrate 201, and the black matrix pattern 207 and the light-emitting unit 202 are separated by a second distance D5 in the direction perpendicular to the base substrate 201, with the ratio of the first distance D4 to the second distance D5 greater than or equal to 2. Within this range, the distance between the black matrix pattern 207 and the light-emitting unit 202 is smaller than the distance between the black matrix pattern 207 and the first light-transmitting structure 204. This configuration prevents the black matrix pattern 207 from blocking the light rays emitted by the light-emitting units 202. Further, the ratio of the first distance D4 to the second distance D5 is greater than or equal to 10.

Exemplarily, the thickness of both the first inorganic encapsulation layer 209 and the second inorganic encapsulation layer 2082 is in the range of 1 micron to 2 microns, and the thickness of the organic encapsulation layer 2081 is in the range of 6 microns to 18 microns.

In the embodiments of the present disclosure, the black matrix pattern in the display panel is positioned at a greater distance from the protruding structure, enabling the luminous output of the display panel greater than the luminous output of a display panel provided with a color filter on encapsulation (COE) in the related art.

In another type of display panel in the related art, an enhanced efficiency structure (EES) technology is applied. The display panel includes a base substrate, a plurality of light-emitting units disposed on the base substrate, as well as a first light-transmitting layer and a second light-transmitting layer provided above the plurality of light-emitting units. The first light-transmitting layer is provided with opening holes, which directly face the light-emitting units. The second light-transmitting layer fills the opening holes in the first light-transmitting layer. This configuration creates a lens-like structure at the opening holes, thereby improving the luminous efficiency of the display panel. The display panel in the embodiments of the present disclosure not only increases the luminous efficiency in the region directly facing the light-emitting units of the display panel, but also enhances the luminous efficiency in the regions between the light-emitting units of the display panel. Therefore, the display panel in the embodiments of the present disclosure has a higher luminous efficiency compared to display panels in the related art.

As shown in FIG. 13, FIG. 13 is a schematic structural diagram of another display panel according to some embodiments of the present disclosure. The display panel 200 according to the embodiments of the present disclosure further includes a touch layer, which is disposed between the light-transmitting layer 208 and the protruding structures 203 and configured to enable touch function. Exemplarily, the touch layer includes a first touch metal layer (tc1), a second touch metal layer (tc2), and an intermediate insulation layer (tr) disposed between the first touch metal layer (tc1) and the second touch metal layer (tc2).

In some embodiments, as shown in FIG. 13, the display panel 200 further includes a pixel definition layer 210. The pixel definition layer 210 is provided with pixel openings 2101, and the light-emitting units 202 are disposed within the pixel openings 2101. The light-emitting unit 202 includes an anode 202a, a light-emitting material layer 202b, and a cathode 202c.

The pixel openings 2101 are configured to indicate the effective light-emitting region of the light-emitting unit 202. The edge of the orthographic projection of the protruding structure 203 on the base substrate 201 and the edge of the orthographic projection of the pixel opening 2101 on the base substrate 201 are separated by a specified distance D2. The specified distance D2 is greater than or equal to 0 micron and less than or equal to 5 microns. The distance D3 between the edge of the orthographic projection of the black matrix pattern 207 on the base substrate 201 and the edge of the orthographic projection of the pixel opening 2101 on the base substrate 201 is greater than or equal to 0 micron and less than or equal to 2 microns.

In this way, it is possible to prevent the protruding structures 203 from affecting the front light emission of the light-emitting units 202, wherein the front light emission refers to the light emission from the light-emitting units 202 in the direction perpendicular to the base substrate 201, and to prevent the black matrix pattern 207 from blocking the light rays illuminating the protruding structures 203 due to a large distance between the protruding structures 203 in the direction parallel to the base substrate 201.

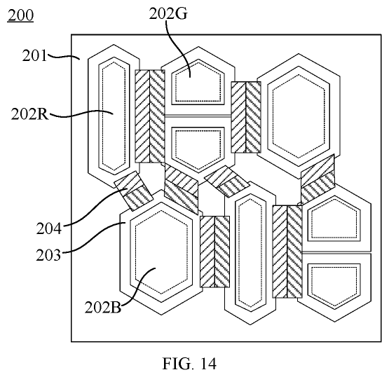

It should be noted that FIG. 14 is a schematic structural diagram of another display panel 200 illustrated according to some embodiments of the present disclosure. In the embodiments of the present disclosure, the light-emitting units 202 have various arrangement modes, such as the arrangement mode shown in FIG. 11 or the arrangement mode shown in FIG. 14. In different arrangement modes, the shape of the protruding structure 203 is adjusted according to the shape of the projection of the light-emitting unit 202 on the base substrate 201.

In summary, a display panel is provided according to the embodiments of the present disclosure, which includes a base substrate, a plurality of light-emitting units, a plurality of protruding structures, and a first light-transmitting structure. The first light-transmitting structure is disposed between two protruding structures corresponding to two adjacent light-emitting units. Additionally, the first light-transmitting structure covers at least a portion of the sidewall of the protruding structure. In this way, as the refractive index of the first light-transmitting structure is greater than that of the protruding structure, the interface between the first light-transmitting structure and the protruding structure can reflect part of the light rays emitted by the light-emitting unit to the region directly facing the display panel, so as to improve the luminous efficiency of the display panel, solve the problem of low luminous efficiency of display panels in related art, and achieve the effect that improves the luminous efficiency of the display panel.

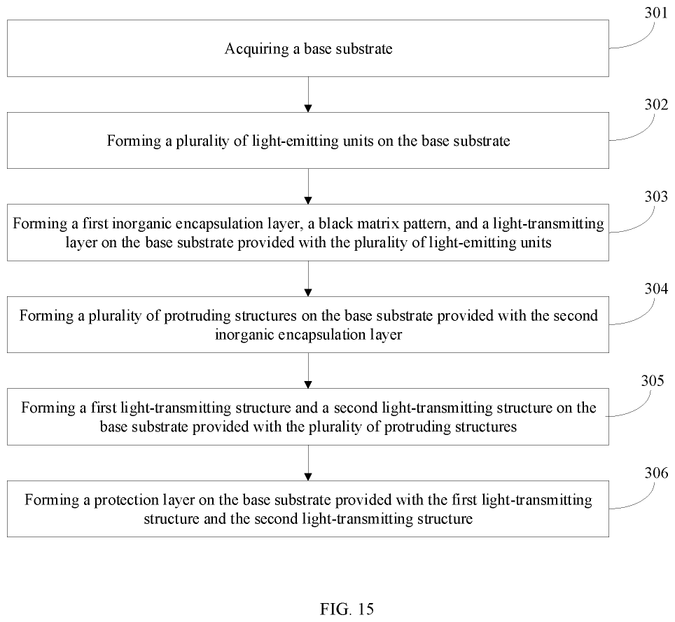

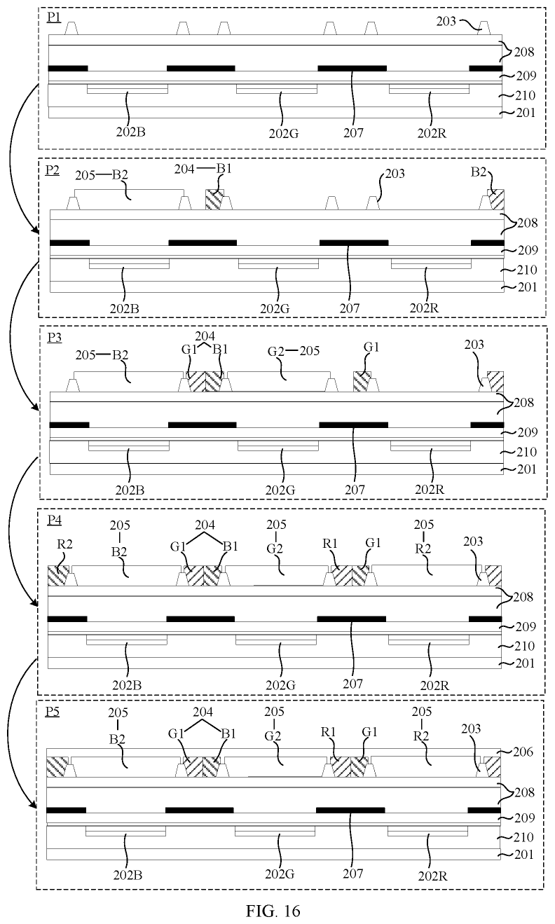

FIG. 15 is a flowchart illustrating a method for manufacturing a display panel according to some embodiments of the present disclosure. The method can be used to manufacture any one of the display panels provided according to the above embodiments. FIG. 16 is a schematic structural diagram of the process for manufacturing the display panel corresponding to FIG. 15. The manufacturing process of the display panel shown in FIG. 15 can be referenced in FIG. 16. The method includes the following steps:

In step 301, a base substrate is acquired.

The base substrate is a flexible substrate, which is made of flexible materials such as polyimide (PI) material. Alternatively, the base substrate is a glass substrate. The base substrate further includes drive circuits.

In step 302, a plurality of light-emitting units are formed on the base substrate.

Before forming the light-emitting units, a pixel definition layer is formed, which includes pixel openings and pixel partitions between two adjacent pixel openings. The light-emitting unit includes an anode, a light-emitting material layer, and a cathode.

In step 303, a first inorganic encapsulation layer, a black matrix pattern, and a light-transmitting layer are formed on the base substrate provided with the plurality of light-emitting units.

The light-transmitting layer includes an organic encapsulation layer and a second inorganic encapsulation layer.

In step 304, a plurality of protruding structures are formed on the base substrate provided with the second inorganic encapsulation layer.

The protruding structures are disposed on the base substrate provided with the light-emitting units. The protruding structures correspond to the light-emitting units, and the orthographic projection of each protruding structure on the base substrate surrounds the orthographic projection of the corresponding light-emitting unit on the base substrate. As shown by P1 in FIG. 16, the plurality of protruding structures may take on a frustum shape. The orthographic projection of the pixel partition between two adjacent pixel openings may overlap with the orthographic projections of two adjacent protruding structures on the base substrate. An optical material layer is coated on the side of the inorganic encapsulation layer distal to the base substrate first, and then the optical material layer is processed into a plurality of protruding structures through a patterning process. The patterning process involved in the embodiments of the present disclosure includes coating with photoresist, exposure, development, etching, and stripping of the photoresist.

In step 305, a first light-transmitting structure and a second light-transmitting structure are formed on the base substrate with the plurality of protruding structures.

The first light-transmitting structure 204 includes a first red color resistance block R1, a first green color resistance block G1, and a first blue color resistance block B1. The second light-transmitting structure 205 includes a second red color resistance block R2, a second green color resistance block G2, and a second blue color resistance block B2. As shown by P2 to P4 in FIG. 16, the first red color resistance block R1 and the second red color resistance block R2 are formed using the same patterning process. The first blue color resistance block B1 and the second blue color resistance block B2 are formed using the same patterning process. The first green color resistance block G1 and the second green color resistance block G2 are formed using the same patterning process. This reduces the manufacturing steps of the display panel.

In step 306, a protection layer is formed on the base substrate provided with the first light-transmitting structure and the second light-transmitting structure.

As shown by P5 in FIG. 16, the protection layer is formed on the side of the first light-transmitting structure and the second light-transmitting structure distal to the base substrate through a coating process.

In summary, a method for manufacturing a display panel is provided according to the embodiments of the present disclosure. The display panel includes a base substrate, a plurality of light-emitting units, a plurality of protruding structures, and a first light-transmitting structure. The first light-transmitting structure is disposed between two protruding structures corresponding to two adjacent light-emitting units. Additionally, the first light-transmitting structure covers at least a portion of the sidewall of the protruding structure. In this way, as the refractive index of the first light-transmitting structure is greater than that of the protruding structure, the interface between the first light-transmitting structure and the protruding structure can reflect part of the light rays emitted by the light-emitting unit to the region directly facing the display panel, so as to improve the luminous efficiency of the display panel, solve the problem of low luminous efficiency of display panels in related art, and achieve the effect that improves the luminous efficiency of the display panel.

In addition, a display device is further provided according to the embodiments of the present disclosure. The display device includes any one of the display panels provided according to the above embodiments. The display device includes various devices with display functions, such as smartphones, tablets, desktop computers, laptops, gaming consoles, smart wearable devices, televisions, advertising displays, and the like. As the display device includes the display panel provided according to the above embodiments, and further has the beneficial effects of the aforementioned display panel, reference can be made to the above embodiments, and the embodiments of the present application will not be repeated herein.

It should be noted that in the accompanying drawings, the dimensions of the layers and regions may be exaggerated for clarity of illustration. Also, it should be understood that in the case that an element or layer is referred to as being “above” another element or layer, it may be directly on the other element, or an intermediate layer may be present. In addition, it should be understood that in the case that an element or layer is referred to as being “under” another element or layer, it may be directly under the other element, or one or more intermediate layers or elements may be present. In addition, it should also be understood that in the case that a layer or element is referred to as being “between” two layers or elements, it may be the only layer between the two layers or elements, or one or more intermediate layers or elements may also be present. Like reference numerals refer to like elements throughout the present disclosure.

In the present disclosure, the terms “first”, “second”, “third”, and “fourth” are merely used for descriptive purposes and should not be construed as indicating or implying relative importance. The term “a plurality of” refers to two or more, unless otherwise explicitly defined.

Described above are merely optional embodiments of the present disclosure and are not intended to limit the present disclosure. Any modifications, equivalents, improvements, and the like, made within the spirit and principle of the present disclosure should fall within the protection scope of the present disclosure.

1. A display panel, comprising:
a base substrate;
a plurality of light-emitting units disposed on the base substrate;
a plurality of protruding structures disposed on the base substrate provided with the light-emitting units, wherein the protruding structures correspond to the light-emitting units, and an orthographic projection of the protruding structure on the base substrate surrounds an orthographic projection of a corresponding light-emitting unit on the base substrate; and
a first light-transmitting structure disposed on the base substrate provided with the protruding structures, wherein the first light-transmitting structure is disposed between two protruding structures corresponding to two adjacent light-emitting units; the first light-transmitting structure covers at least a portion of a sidewall of the protruding structure; and refractive index of a material of the first light-transmitting structure is greater than refractive index of a material of the protruding structure.

2. The display panel according to claim 1, wherein the protruding structure is in a prismoid shape, with dimensions of the protruding structure on one side proximal to the base substrate larger than dimensions of the protruding structure on one side distal to the base substrate.

3. The display panel according to claim 1, further comprising a second light-transmitting structure, wherein the second light-transmitting structure is disposed within a region surrounded by the protruding structure; the second light-transmitting structure covers at least a portion of a sidewall of the protruding structure; and refractive index of a material of the second light-transmitting structure is greater than the refractive index of the material of the protruding structure.

4. The display panel according to claim 3, further comprising a protection layer, wherein the protection layer is disposed on one side of the first light-transmitting structure and the second light-transmitting structure distal to the base substrate, and the protection layer covers the first light-transmitting structure and the second light-transmitting structure.

5. The display panel according to claim 4, wherein refractive index of a material of the protection layer is greater than the refractive index of the material of the first light-transmitting structure, and the refractive index of the material of the protection layer is greater than the refractive index of the material of the second light-transmitting structure.

6. The display panel according to claim 4, wherein the first light-transmitting structure and the protection layer are of an integrated structure.

7. The display panel according to claim 6, wherein the refractive index of the material of the first light-transmitting structure is greater than the refractive index of the material of the second light-transmitting structure.

8. The display panel according to claim 3, wherein the plurality of light-emitting units comprise two adjacent target light-emitting units, and the first light-transmitting structure comprises a first color resistance block and a second color resistance block, wherein the first color resistance block and the second color resistance block are disposed between two protruding structures corresponding to the two adjacent target light-emitting units; and
the second light-transmitting structure comprises a third color resistance block and a fourth color resistance block, wherein the third color resistance block and the fourth color resistance block are respectively disposed within regions surrounded by the two protruding structures corresponding to the two adjacent target light-emitting units;
wherein the second color resistance block is disposed on one side of the first color resistance block distal to the third color filter block, the first color resistance block and the fourth color resistance block have a same color, and the second color resistance block and the third color resistance block have a same color.

9. The display panel according to claim 8, wherein a ratio of area A of an orthographic projection of the first color resistance block on the base substrate to area B of an orthographic projection of the second color resistance block on the base substrate, as well as a ratio of area D of an orthographic projection of the fourth color resistance block on the base substrate to area C of an orthographic projection of the third color resistance block on the base substrate satisfy a formula:
$$A / B = x ( D / C ) ;$$
where x is a predetermined coefficient greater than 0.

10. The display panel according to claim 3, further comprising a black matrix pattern and a light-transmitting layer, wherein
the light-emitting units, the black matrix pattern, the light-transmitting layer, and the first light-transmitting structure are arranged sequentially along a direction distal to the base substrate; and
the black matrix pattern is provided with a first opening; a projection of the first light-transmitting structure on the base substrate is located within a projection of the black matrix pattern on the base substrate, and an orthographic projection of the second light-transmitting structure on the base substrate is located within an orthographic projection of the first opening on the base substrate.

11. The display panel according to claim 10, further comprising a first inorganic encapsulation layer, wherein the first inorganic encapsulation layer is disposed between the black matrix pattern and the light-emitting units;
the light-transmitting layer comprises an organic encapsulation layer and a second inorganic encapsulation layer, with the second inorganic encapsulation layer disposed on one side of the organic encapsulation layer distal to the black matrix pattern.

12. The display panel according to claim 10, wherein the black matrix pattern and the first light-transmitting structure are separated by a first distance in a direction perpendicular to the base substrate, and the black matrix pattern and the light-emitting unit are separated by a second distance in the direction perpendicular to the base substrate, with a ratio of the first distance to the second distance greater than or equal to 2.

13. The display panel according to claim 1, further comprising a pixel definition layer, wherein the pixel definition layer is provided with pixel openings, and the light-emitting units are disposed within the pixel openings;
an edge of the orthographic projection of the protruding structure on the base substrate and an edge of an orthographic projection of the pixel opening on the base substrate are separated by a specified distance, the specified distance being greater than or equal to 0 micron and less than or equal to 5 microns.

14. The display panel according to claim 2, wherein the protruding structure includes a top surface, a bottom surface, and a sidewall connecting the bottom surface and the top surface, an included angle between the sidewall and the bottom surface is in a range of 20° to 90°.

15. A display device, comprising a display panel, wherein the display panel comprises:
a base substrate;
a plurality of light-emitting units disposed on the base substrate;
a plurality of protruding structures disposed on the base substrate provided with the light-emitting units, wherein the protruding structures correspond to the light-emitting units, and an orthographic projection of the protruding structure on the base substrate surrounds an orthographic projection of a corresponding light-emitting unit on the base substrate; and
a first light-transmitting structure disposed on the base substrate provided with the protruding structures, wherein the first light-transmitting structure is disposed between two protruding structures corresponding to two adjacent light-emitting units; the first light-transmitting structure covers at least a portion of a sidewall of the protruding structure; and refractive index of a material of the first light-transmitting structure is greater than refractive index of a material of the protruding structure.

16. The display device according to claim 15, wherein the protruding structure is in a prismoid shape, with dimensions of the protruding structure on one side proximal to the base substrate larger than dimensions of the protruding structure on one side distal to the base substrate.

17. The display device according to claim 15, further comprising a second light-transmitting structure, wherein the second light-transmitting structure is disposed within a region surrounded by the protruding structure; the second light-transmitting structure covers at least a portion of a sidewall of the protruding structure; and refractive index of a material of the second light-transmitting structure is greater than the refractive index of the material of the protruding structure.

18. The display device according to claim 17, further comprising a protection layer, wherein the protection layer is disposed on one side of the first light-transmitting structure and the second light-transmitting structure distal to the base substrate, and the protection layer covers the first light-transmitting structure and the second light-transmitting structure.

19. The display device according to claim 18, wherein refractive index of a material of the protection layer is greater than the refractive index of the material of the first light-transmitting structure, and the refractive index of the material of the protection layer is greater than the refractive index of the material of the second light-transmitting structure.

20. The display device according to claim 18, wherein the first light-transmitting structure and the protection layer are of an integrated structure.
